(19) United States
(12) Patent Application Publication
(10) Pub. No.: US 2021/0181267 A1
(43) Pub. Date: Jun. 17, 2021

(54) MICRO LED BOND TESTER AND METHOD OF EVALUATING MICRO LED BOND USING SAME

(71) Applicant: SEOUL VIOSYS CO., LTD., Ansan-si (KR)

(72) Inventors: Young Ju LEE, Ansan-si (KR); lk Kyu YOU, Ansan-si (KR); Jung Jae LEE, Ansan-si (KR)

(21) Appl. No.: 17/121,638

(22) Filed: Dec. 14, 2020

Related U.S. Application Data
(60) Provisional application No. 62/949,087, filed on Dec. 17, 2019.

(51) Int. Cl. G01R 31/70; H01L 25/13

(52) U.S. Cl. CPC G01R 31/70; H01L 25/13

(57) ABSTRACT

A micro LED bond tester including a stage configured to mount a circuit board on which micro LEDs are mounted, and a gas blower configured to blow gas into at least one of the micro LEDs on the circuit board.

### CROSS REFERENCE TO RELATED APPLICATION

This application claims the benefit of U.S. Provisional Patent Application No. 62/949,087 filed on Dec. 17, 2019, which is hereby incorporated by reference for all purposes as if fully set forth herein.

### BACKGROUND

### Field

Exemplary embodiments relate to a micro LED bond tester and a method of evaluating a micro LED bond using the same.

### Discussion of the Background

As an inorganic light source, light emitting diodes have been used in various fields including displays, vehicular lamps, general lighting, and the like. With various advantages of light emitting diodes over conventional light sources, such as longer lifespan, lower power consumption, and rapid response, light emitting diodes have been replacing conventional light sources.

Light emitting diodes have been generally used as backlight light sources in display apparatuses. However, recently, LED display apparatuses that directly display an image using micro LEDs have been developed.

In general, a display apparatus realizes various colors through mixture of blue, green, and red light. To display various images, the display apparatus includes a plurality of pixels each including sub-pixels that correspond to blue, green, and red light, respectively. In this manner, a color of a certain pixel is determined based on the colors of the sub-pixels and images can be displayed through combination of such pixels.

LEDs can emit light of various colors depending on their materials. As such, a display apparatus may be provided by employing individual micro LEDs emitting blue, green, and red arranged on a two-dimensional plane, or by employing micro LEDs having a stacked structure, in which a blue LED, a green LED, and a red LED are stacked one above another and arranged on a two-dimensional plane.

Micro LEDs used in one display apparatus usually require more than one million even for a small-sized display. Due to the small size of micro LEDs and the enormous number required, mass production of micro LED display apparatus with a conventional technology is almost impossible since the conventional die bonding technology mounts the LED chips individually. Accordingly, a technology for transferring a plurality of micro LEDs onto a circuit board in a group has been recently developed. In such technology, micro LEDs may be bonded to the circuit board using a metal bonding layer, an anisotropic conductive film, or others.

When transferring micro LEDs in a group, it is necessary to evaluate bonding characteristics of micro LEDs. In particular, micro LEDs with bonding failure should be replaced with new micro LEDs. To this end, a micro LED that has the bonding failure needs to be specified among the micro LEDs transferred onto the circuit board. In general, the micro LEDs are visually inspected to evaluate whether the bonding of a micro LEDs has failed, but the bonding force may vary for each micro LED. In addition, even when a micro LED passes visual inspection, the micro LED may still have a failure in bonding. In particular, due to the very small size of micro LEDs, evaluating their bonding characteristics is very difficult, especially when enormous number needs to be evaluated. As such, a new technique is required to assess bonding failure in micro LEDs other than visual inspection.

The above information disclosed in this Background section is only for understanding of the background of the inventive concepts, and, therefore, it may contain information that does not constitute prior art.

### SUMMARY

Micro LED bond testers and a method of evaluating a micro LED bond according to exemplary embodiments of the invention are capable of easily evaluating bonding failure of micro LEDs.

Additional features of the inventive concepts will be set forth in the description which follows, and in part will be apparent from the description, or may be learned by practice of the inventive concepts.

A micro LED bond tester according to an exemplary embodiment includes a stage configured to mount a circuit board on which micro LEDs are mounted, and a gas blower configured to blow gas into at least one of the micro LEDs on the circuit board.

The gas blower may include a needle including a gas outlet, a pressure control device to regulate a gas pressure, and a supply pipe to deliver gas.

The outlet of the needle may have an inner diameter of about 10 μm to about 50 μm.

The micro LED bond tester may further include a camera configured to observe the micro LED.

The stage may be movable in first and second directions intersecting each other.

The micro LEDs may be configured to emit blue light, green light, and red light, respectively.

The micro LEDs may be configured to emit light of any one of blue light, green light, and red light, respectively.

The gas may be He or N2 gas.

A method of evaluating a bonding of a micro LED according to another exemplary embodiment includes arranging a circuit board mounted with the micro LEDs on a stage, blowing gas at a predetermined pressure on at least one of the micro LEDs mounted on the circuit board using a gas blower, observing the micro LED applied with the gas, and determining whether the bonding of the micro LED has a failure according to an observation result.

The bonding of the micro LED may be determined to be failed when the micro LED applied with gas is detached from the circuit board.

A plurality of target micro LEDs may be selected among the micro LEDs to obtain the observation result thereof.

The target micro LEDs may be randomly selected.

The target micro LEDs may be regularly selected.

The target micro LEDs may be selected by pre-evaluating relatively weak bonding locations on the circuit board.

The gas may be He or N2 gas.

The method may further include moving the stage along first or section directions intersecting each other to evaluate another one of the micro LEDs mounted on the circuit board.

The bonding of the micro LED may be determined to be failed when the micro LED applied with gas shakes more than a predetermine level.

The method may further include moving the gas blower along first or section directions intersecting each other to evaluate another one of the micro LEDs mounted on the circuit board.

The method may further include moving a camera for observing the micro LED along with the gas blower.

The gas blower may include a needle having an inner diameter of about 10 μm to about 50 μm.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the inventive concepts.

FIG. 1 is a schematic plan view of a display panel on which micro LEDs are mounted according to an exemplary embodiment.

FIG. 2 is a schematic cross-sectional view taken along line A-A′ of FIG. 1.

FIG. 3 is a schematic view illustrating a micro LED bond tester and a method of evaluating a micro LED bond using the same according to an exemplary embodiment.

FIG. 4 is a schematic plan view illustrating targets for bonding evaluation among micro LEDs on a circuit board.

### DETAILED DESCRIPTION

In the following description, for the purposes of explanation, numerous specific details are set forth in order to provide a thorough understanding of various exemplary embodiments or implementations of the invention. As used herein “embodiments” and “implementations” are interchangeable words that are non-limiting examples of devices or methods employing one or more of the inventive concepts disclosed herein. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

In exemplary embodiments, a micro bond tester, and/or one or more components thereof, may be implemented via one or more general purpose and/or special purpose components, such as one or more discrete circuits, digital signal processing chips, integrated circuits, application specific integrated circuits, microprocessors, processors, programmable arrays, field programmable arrays, instruction set processors, and/or the like.

According to one or more exemplary embodiments, the features, functions, processes, etc., described herein may be implemented via software, hardware (e.g., general processor, digital signal processing (DSP) chip, an application specific integrated circuit (ASIC), field programmable gate arrays (FPGAs), etc.), firmware, or a combination thereof. In this manner, a micro bond tester, and/or one or more components thereof may include or otherwise be associated with one or more memories (not shown) including code (e.g., instructions) configured to cause a micro bond tester, and/or one or more components thereof to perform one or more of the features, functions, processes, etc., described herein.

The memories may be any medium that participates in providing code to the one or more software, hardware, and/or firmware components for execution. Such memories may be implemented in any suitable form, including, but not limited to, non-volatile media, volatile media, and transmission media. Non-volatile media include, for example, optical or magnetic disks. Volatile media include dynamic memory. Transmission media include coaxial cables, copper wire and fiber optics. Transmission media can also take the form of acoustic, optical, or electromagnetic waves. Common forms of computer-readable media include, for example, a floppy disk, a flexible disk, hard disk, magnetic tape, any other magnetic medium, a compact disk-read only memory (CD-ROM), a rewriteable compact disk (CD-RW), a digital video disk (DVD), a rewriteable DVD (DVD-RW), any other optical medium, punch cards, paper tape, optical mark sheets, any other physical medium with patterns of holes or other optically recognizable indicia, a random-access memory (RAM), a programmable read only memory (PROM), and erasable programmable read only memory (EPROM), a FLASH-EPROM, any other memory chip or cartridge, a carrier wave, or any other medium from which information may be read by, for example, a controller/processor.

Hereinafter, exemplary embodiments of the inventive concepts will be described in detail with reference to the accompanying drawings.

Micro LEDs according to exemplary embodiments may be used in a VR display apparatus such as a smart watch or a VR headset, or an AR display apparatus such as augmented reality glasses, without being limited thereto. In these display apparatuses, a display panel is mounted on which the micro LEDs are mounted to implement an image.

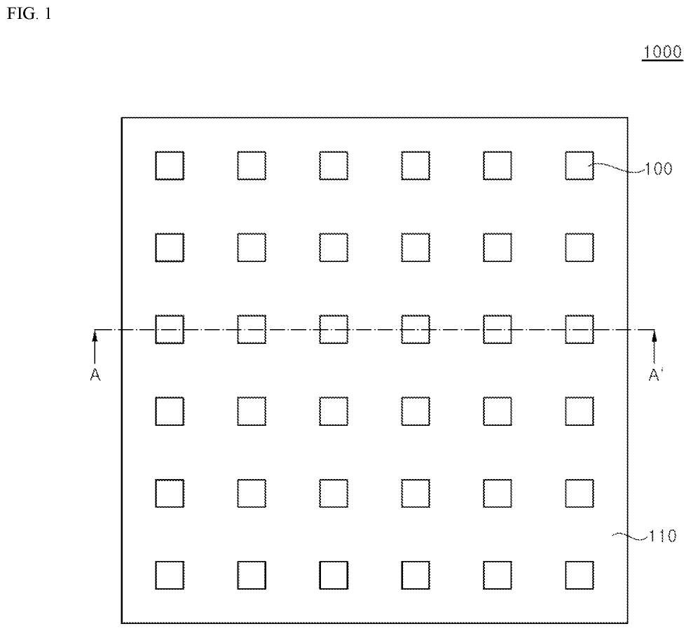

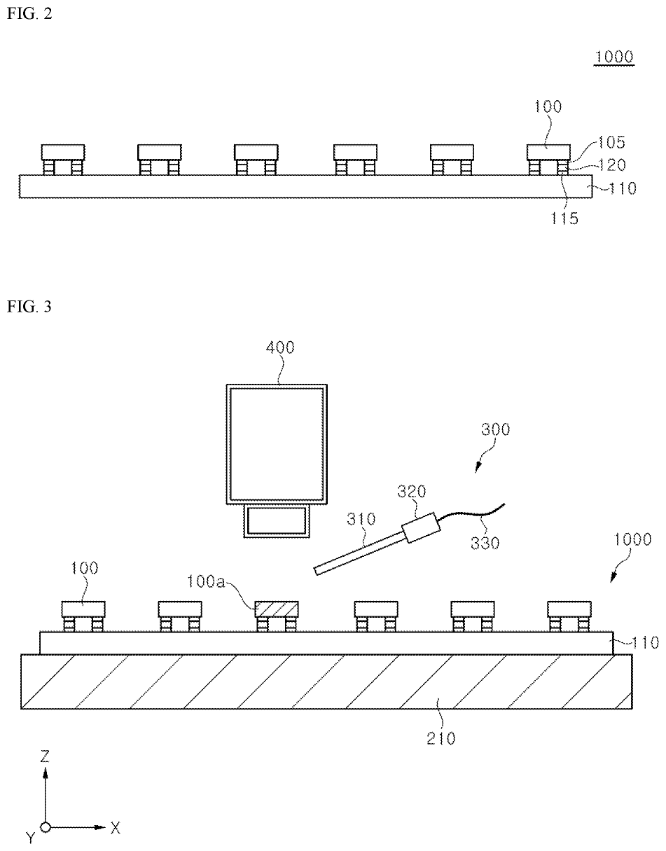

FIG. 1 is a schematic plan view illustrating a display panel 1000 according to an exemplary embodiment, and FIG. 2 is a schematic cross-sectional view taken along line A-A′ of FIG. 1.

Referring to FIGS. 1 and 2, the display panel 1000 includes micro LEDs 100 mounted on a circuit board 110. The circuit board 110 may include a circuit for passive matrix driving or active matrix driving. In an exemplary embodiment, the circuit board 110 may include interconnection lines and resistors therein. In another exemplary embodiment, the circuit board 110 may include interconnection lines, transistors, and capacitors. For example, the circuit board 110 may be a glass substrate including a thin film transistor. The circuit board 110 may also have pads disposed on an upper surface thereof to allow electrical connection to the circuit therein. The micro LEDs 100 may have, for example, a size smaller than 500 μm×500 μm, and further, smaller than 100 μm×100 μm.

A plurality of micro LEDs 100 is arranged on the circuit board 110. The micro LEDs 100 may be mounted on the circuit board 110 by group transfer. In an exemplary embodiment, the micro LEDs 100 may be bonded on the circuit board 110 using a metal bonding material, such as AuSn, CuSn, or In. In another exemplary embodiment, the micro LEDs 100 may be bonded to the circuit board 110 using an anisotropic conductive film (ACF), an anisotropic conductive paste (ACP), an anisotropic conductive adhesive (ACA), or the like.

A structure of the micro LEDs 100 is not particularly limited. In an exemplary embodiment, the micro LEDs 100 may be sub-pixels that emit light of a specific color, and these sub-pixels may constitute one pixel. For example, a blue LED, a green LED, and a red LED may be disposed adjacent to one another on a plane to form one pixel. In another exemplary embodiment, each of the micro LEDs 100 may have a stacked structure emitting light of various colors. For example, each of the micro LEDs 100 may have a structure in which a blue LED, a green LED, and a red LED are stacked to overlap one another. In this case, one light emitting device may form one pixel.

The micro LEDs 100 may have pads 105, and the pads 105 may be adhered to corresponding pads 115 of the circuit board 110 through a bonding layer 120.

For the micro LEDs 100 mounted on the circuit board 110, bonding characteristics thereof would need to be evaluated. In particular, bonding failure may occur in a portion of the micro LEDs 100 during a process of being transferred in a group.

However, since the micro LEDs 100 are small-sized and an enormous number thereof is transferred, it is difficult to evaluate the bonding failure of each micro LEDs 100. In general, a die shear test (DTS) may be performed to evaluate bonding failure of a conventional light emitting diode package. However, since the DTS requires physical contact, the DTS may not be applicable to the micro LEDs due to the small size thereof.

Exemplary embodiments provide a micro LED bond tester that can evaluate a micro LED bond and a method of evaluating the micro LED bond using the same. Hereinafter, the micro LED bond tester and the method of evaluating the micro LED bond will be described with reference to FIG. 3.

FIG. 3 is a schematic view illustrating a micro LED bond tester and a method of evaluating a micro LED bond using the same according to an exemplary embodiment.

Referring to FIG. 3, the bond tester according to an exemplary embodiment may include a stage 210, a gas blower 300, and a camera 400.

The stage 210 may provide a space to which the display panel 1000 can be disposed. The display panel 1000 may be placed on the stage 210 and may be clamped to be fixed on the stage 210.

The stage 210 may be movable in X and Y directions, and may also be movable in the Z direction. For example, when the display panel 1000 is transferred, the stage 210 may move downward in the Z direction to receive the display panel 1000, and thereafter, move upward to evaluate bonding of micro LEDs 100. In addition, the stage 210 may be movable in the X and Y directions to move a selected micro LED 100a to be evaluated to an evaluation location.

The gas blower 300 may include a needle 310 having a gas outlet, a pressure control device 320, and a gas supply pipe 330. The needle 310 may have a gas outlet having a small inner diameter to blow gas into a narrow region targeting a micro LED 100a to be evaluated. For example, the gas outlet may have an inner diameter of about 10 μm to about 50 μm, without being limited thereto.

The pressure control device 320 may adjust a pressure of gas so that gas can be released at a pressure suitable for evaluating bonding characteristics of the micro LED 100a. The pressure suitable for evaluating bonding characteristics of the micro LED 100a may be predetermined through a test. The pressure control device 320 may adjust gas to be released at a constant pressure through the gas outlet, but the inventive concepts are not limited thereto. In some exemplary embodiments, the pressure of the released gas may be adjusted to gradually increase or gradually decrease.

The gas supply pipe 330 supplies gas to the pressure control device 320 from a storage tank storing gas. The gas supply pipe 330 may be a flexible tube to move the needle 310 as desired, without being limited thereto.

In the illustrated exemplary embodiment, gas may be air or an inert gas, such as He or N₂. The inert gas may not cause oxidation of a metal bonding layer.

The camera 400 may observe the micro LED 100a to which gas is applied from the needle 310. The camera 400 may capture an image of the micro LED 100a on the circuit board 110 in the vertical direction, but the inventive concepts are not limited thereto.

In the illustrated exemplary embodiment, the stage 210 is exemplarily illustrated and described as being disposed under the gas blower 300 and the camera 400. However, the inventive concepts are not limited thereto, and in some exemplary embodiments, the stage 210 may be disposed above, and the camera 400 and the gas blower 300 may be disposed below.

Hereinafter, a method of evaluating a micro LED bond according to an exemplary embodiment will be described.

After the micro LEDs 100 are transferred onto the circuit board 110, the display panel 1000 is disposed on the stage 210. The stage 210 moves in the Z-direction, X-direction, and/or Y-direction so that a micro LED 100a to be evaluated is placed in an evaluation location, that is, a location where gas is to be released from the needle 310. The camera 400 is disposed on the micro LED 100a to be evaluated.

Subsequently, the gas blower 300 applies gas to the micro LED 100a through the needle 310. The gas blower 300 releases gas at a predetermined pressure to evaluate bonding characteristics using the pressure control device 320.

The camera 400 observes whether the micro LED 100a is detached/attached or shaken by gas. When it is observed that the micro LED 100a is detached/attached or shaken by gas, bonding of the micro LED 100a may be determined to be failed. When the micro LED 100a is fixed and does not move by gas, bonding thereof may be determined to be good.

When the bonding evaluation is completed for one micro LED, the stage 210 is moved to place another micro LED 100 in the evaluation location, and the evaluation is again performed using gas. However, the inventive concepts are not limited thereto. In another exemplary embodiment, the stage 210 may be fixed after the evaluation, but the gas blower 300 may move to the next micro LED 100 for evaluation. In this case, the camera 400 may move together with the gas blower 300, or the camera 400 may adjust an angle to observes the next micro LED 100. In still another exemplary embodiment, both of the stage 210 and the gas blower 300 may move to evaluate the next micro LED. By repeating this process, the bonding evaluation of the micro LEDs 100 may be completed.

When the bonding evaluation is completed, the micro LEDs determined to be failed may be repaired, or the display panel 1000 may be discarded when the repair process is not feasible.

Due to the excessive number of the micro LEDs 100 mounted on the circuit board 110, performing bonding evaluation on each of the micro LEDs may require excessive amount of time. As such, bonding evaluation may be performed only on a portion of the micro LEDs 100 on the circuit board 110. However, the inventive concepts are not limited thereto. In some exemplary embodiments, a bond tester may include a stage, a plurality of gas blowers, and a plurality of cameras. When the bond tester includes multiple gas blowers and cameras, a greater number of micro LEDs 100a may be evaluated at a given time. Since a method of evaluating bonding of multiple micro LEDs 100a simultaneously is substantially the same as that for a single micro LED 100a, repeated descriptions thereof will be omitted.

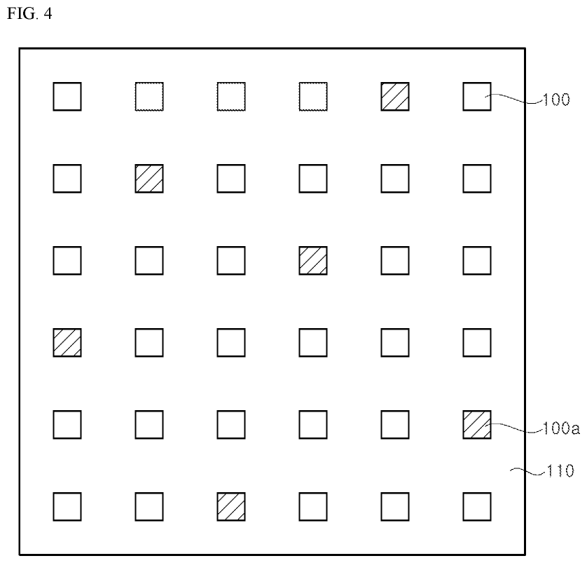

FIG. 4 is a schematic plan view illustrating targets for bonding evaluation among micro LEDs on a circuit board.

Referring to FIG. 4, bonding evaluation is performed on a portion of micro LEDs 100 on a circuit board 110, that is, micro LEDs 100a.

The micro LEDs 100a may be randomly or regularly selected according to a display panel 1000 disposed on a stage 210. For example, the micro LEDs 100 for bonding evaluation may be randomly or regularly selected using software or the like.

In another exemplary embodiment, bonding performance of the micro LEDs 100 mounted on the circuit board 110 may be examined in advance to identify a location where bonding of the micro LEDs is weak, and bonding evaluation may be performed on the micro LEDs 100 disposed at the location where bonding of the micro LEDs is weak. For example, a single display panel 1000 may be thoroughly examined to evaluate bonding performance for each location, and locations with bonding failure may be selected in advance through the examination. When the locations with bonding failure are determined, only the bonding failure of the micro LEDs 100 disposed at the corresponding locations may be evaluated for other display panels 1000 manufactured by the same process.

According to exemplary embodiments, bonding failure of a micro LED may be determined by blowing gas into the micro LED using the gas blower.

Although certain exemplary embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A micro LED bond tester, comprising:
a stage configured to mount a circuit board on which micro LEDs are mounted; and
a gas blower configured to blow gas into at least one of the micro LEDs on the circuit board.

2. The micro LED bond tester of claim 1, wherein the gas blower includes:
a needle including a gas outlet;
a pressure control device to regulate a gas pressure; and
a supply pipe to deliver gas.

3. The micro LED bond tester of claim 2, wherein the outlet of the needle has an inner diameter of about 10 μm to about 50 μm.

4. The micro LED bond tester of claim 2, further comprising a camera configured to observe the micro LED.

5. The micro LED bond tester of claim 1, wherein the stage is movable in first and second directions intersecting each other.

6. The micro LED bond tester of claim 1, wherein the micro LEDs are configured to emit blue light, green light, and red light, respectively.

7. The micro LED bond tester of claim 1, wherein the micro LEDs are configured to emit light of any one of blue light, green light, and red light, respectively.

8. The micro LED bond tester of claim 1, wherein the gas is He or N₂ gas.

9. A method of evaluating a bonding of a micro LED, comprising:
arranging a circuit board mounted with the micro LEDs on a stage;
blowing gas at a predetermined pressure on at least one of the micro LEDs mounted on the circuit board using a gas blower;
observing the micro LED applied with the gas; and
determining whether the bonding of the micro LED has a failure according to an observation result.

10. The method of claim 9, wherein the bonding of the micro LED is determined to be failed when the micro LED applied with gas is detached from the circuit board.

11. The method of claim 9, wherein a plurality of target micro LEDs is selected among the micro LEDs to obtain the observation result thereof.

12. The method of claim 11, wherein the target micro LEDs are randomly selected.

13. The method of claim 11, wherein the target micro LEDs are regularly selected.

14. The method of claim 11, wherein the target micro LEDs are selected by pre-evaluating relatively weak bonding locations on the circuit board.

15. The method of claim 9, wherein the gas is He or N₂ gas.

16. The method of claim 9, further comprising moving the stage along first or section directions intersecting each other to evaluate another one of the micro LEDs mounted on the circuit board.

17. The method of claim 9, wherein the bonding of the micro LED is determined to be failed when the micro LED applied with gas shakes more than a predetermine level.

18. The method of claim 9, further comprising moving the gas blower along first or section directions intersecting each other to evaluate another one of the micro LEDs mounted on the circuit board.

19. The method of claim 18, further comprising moving a camera for observing the micro LED along with the gas blower.

20. The method of claim 9, wherein the gas blower includes a needle having an inner diameter of about 10 μm to about 50 μm.
